(19) United States
(12) Patent Application Publication
(10) Pub. No.: US 2018/0040807 A1
(43) Pub. Date: Feb. 8, 2018

(54) MAGNETIC MEMORY

(71) Applicant: KABUSHIKI KAISHA TOSHIBA, Minato-ku (JP)

(72) Inventors: Yoshiaki SAITO, Kawasaki (JP); Hiroaki Yoda, Kawasaki (JP); Yushi Kato, Chofu (JP); Mizue Ishikawa, Yokohama (JP); Soichi Oikawa, Hachioji (JP)

(73) Assignee: KABUSHIKI KAISHA TOSHIBA, Minato-ku (JP)

(21) Appl. No.: 15/445,475

(22) Filed: Feb. 28, 2017

(30) Foreign Application Priority Data
Aug. 4, 2016 (JP) 2016-153898

(51) Int. Cl. H01L 43/02; H01L 43/10; H01L 27/22; H01L 43/08

(52) U.S. Cl. CPC H01L 43/02; H01L 43/08; H01L 43/10; H01L 27/228

(57) ABSTRACT

A magnetic memory of an embodiment includes: a first terminal to third terminals; a first nonmagnetic layer, which is conductive, including a first portion, a second portion, and a third portion, the first portion being disposed between the second portion and the third portion, the second portion being electrically connected to the first terminal, and the third portion being electrically connected to the second terminal; a first magnetoresistive element including a first magnetic layer electrically connected to the third terminal, a second magnetic layer disposed between the first magnetic layer and the first portion, and a second nonmagnetic layer disposed between the first magnetic layer and the second magnetic layer; and a first layer at least disposed between the first portion and the second magnetic layer, and including at least one of Mg, Al, Si, Hf, or a rare earth element, and at least one of oxygen or nitrogen.

### CROSS REFERENCE TO RELATED APPLICATIONS

This application is based upon and claims the benefit of priority from prior Japanese Patent Application No. 2016-153898 filed on Aug. 4, 2016 in Japan, the entire contents of which are incorporated herein by reference.

### FIELD

Embodiments described herein relate generally to magnetic memories.

### BACKGROUND

Recently, research and development of magnetic memories employing write methods using spin orbit torque or spin Hall effect is being actively performed. The spin Hall effect is a phenomenon caused by a current flowing through a nonmagnetic layer. Due to the influence of the current, electrons having a spin angular momentum (“spin”) are diffused in one direction and electrons having a spin angular momentum in a direction opposite to the one direction are diffused in the opposite direction to cause a spin current Is that flows in a direction perpendicular to the direction in which the current flowing through the nonmagnetic layer. As a result, opposite spins are accumulated around opposite interfaces of the nonmagnetic layer.

A magnetic tunnel junction (MTJ) element includes a first magnetic layer (“reference layer”) in which the magnetization direction is fixed, a second magnetic layer (“storage layer”) in which the magnetization direction is changeable, and a nonmagnetic insulating layer disposed between the first magnetic layer and the second magnetic layer. If the second magnetic layer (storage layer) of the MTJ element is disposed on the aforementioned nonmagnetic layer, and a current is caused to flow through the nonmagnetic layer to generate a spin current in the nonmagnetic layer, the magnetization direction of the storage layer may be switched by the spin orbit torque (SOT) applied to the storage layer by means of the spin current generated in the nonmagnetic layer and the electrons with a spin accumulated near the MTJ element. A magnetic random access memory (MRAM) to which data is written by using the spin orbit torque or spin Hall effect is called “SOT-MRAM.” Data is read from the SOT-MRAM using a magnetoresistive effect (MR effect) of the MTJ element, by causing a read current to flow between the reference layer and the nonmagnetic layer.

An MRAM called STT-MRAM is also known, to which data is written by causing a write current to flow between the storage layer and the reference layer of the MTJ element to apply a spin transfer torque (STT) to the storage layer. Data is read from the STT-MRAM in the same manner as in the write operation, by causing a read current to flow between the storage layer and the reference layer. Thus, the read current path and the write current path are the same in the STT-MRAM. This increases the variation in device characteristics as the device size is decreased. Therefore, it is difficult to secure the margin in each of the read current, the write current, the current flowing through the transistor connected to the MTJ element, and the breakdown current of the nonmagnetic insulating layer of the MTJ element by suppressing the variation in each current.

In contrast, the margin with respect to the variation of each current is greater in the SOT-MRAM since the read current path is different from the write current path. Therefore, the variation in each of the read current, the transistor current, and the breakdown current of the nonmagnetic insulating layer of the MTJ element may be controlled in a manner from the control of the variation in each the write current, the transistor current, and the electromigration current to the nonmagnetic layer. Thus, if the MTJ elements acting as the memory elements are miniaturized (to increase the capacity), the margin with respect to the variation in each current is considerably greater than that of the STT-MRAM. However, at present, the write efficiency of the SOT-MRAM is inferior to that of the STT-MRAM.

### BRIEF DESCRIPTION OF THE DRAWINGS

FIG. 1 is a perspective view of an example of a memory cell of a SOT-MRAM.

FIG. 2 is a perspective view of an example of a memory cell of a STT-MRAM.

FIG. 3 is a photograph used for explaining a problem of the memory cell of the SOT-MRAM.

FIG. 4 is a graph showing the dependency of the spin Hall angle on the thickness of conductive layer.

FIG. 5 is a graph showing the dependency of the variation in coercive force on the thickness of storage layer in an MTJ element.

FIG. 6A is a perspective view showing a magnetic memory according to a first embodiment.

FIG. 6B is a perspective view showing a magnetic memory according to a first modification first embodiment.

FIG. 7A is a perspective view of a magnetic according to a second modification of the first embodiment.

FIG. 7B is a perspective view of a magnetic memory according to a third modification of the first embodiment.

FIG. 8 is a cross-sectional view of a storage layer or reference layer including a multilayer structure.

FIG. 9 is a perspective view of a magnetic memory according to a second embodiment.

FIG. 10 is a perspective view of a magnetic memory according to a modification of the second embodiment.

FIG. 11 is a diagram showing a result of measurement of saturation magnetization Ms of a magnetic memory according to a first example.

FIG. 12 is a diagram showing a result of measurement of coercive force Hc of the magnetic memory according to the first example.

FIG. 13 is a diagram showing a result of evaluation of write current of a magnetic memory according to a second example.

FIG. 14 is a diagram showing a result of measurement of write current of the magnetic memory according to the second example.

FIG. 15 is a diagram showing the dependency of the write current on the thickness of the layer 15 in a magnetic memory according to a third example.

FIG. 16 is a diagram showing the magnetization switching characteristics of a magnetic memory according to a fourth example.

FIG. 17 is a diagram showing the relationship between the voltage applied to an MTJ element and the value of a current caused to flow through the conductive layer, for which the magnetization switching is observed, in the magnetic memory according to the fourth example.

FIG. 18 is a circuit diagram of a magnetic memory according to a third embodiment.

### DETAILED DESCRIPTION

A magnetic memory according to an embodiment includes: a first terminal, a second terminal, and a third terminal; a first nonmagnetic layer, which is conductive, including a first portion, a second portion, and a third portion, the first portion being disposed between the second portion and the third portion, the second portion being electrically connected to the first terminal, and the third portion being electrically connected to the second terminal; a first magnetoresistive element including a first magnetic layer electrically connected to the third terminal, a second magnetic layer disposed between the first magnetic layer and the first portion, and a second nonmagnetic layer disposed between the first magnetic layer and the second magnetic layer; and a first layer at least disposed between the first portion and the second magnetic layer, the first layer including at least one of Mg, Al, Si, Hf, or a rare earth element, and the first layer further including at least one of oxygen or nitrogen.

Before embodiments are described, how the inventors have reached the present invention will be described.

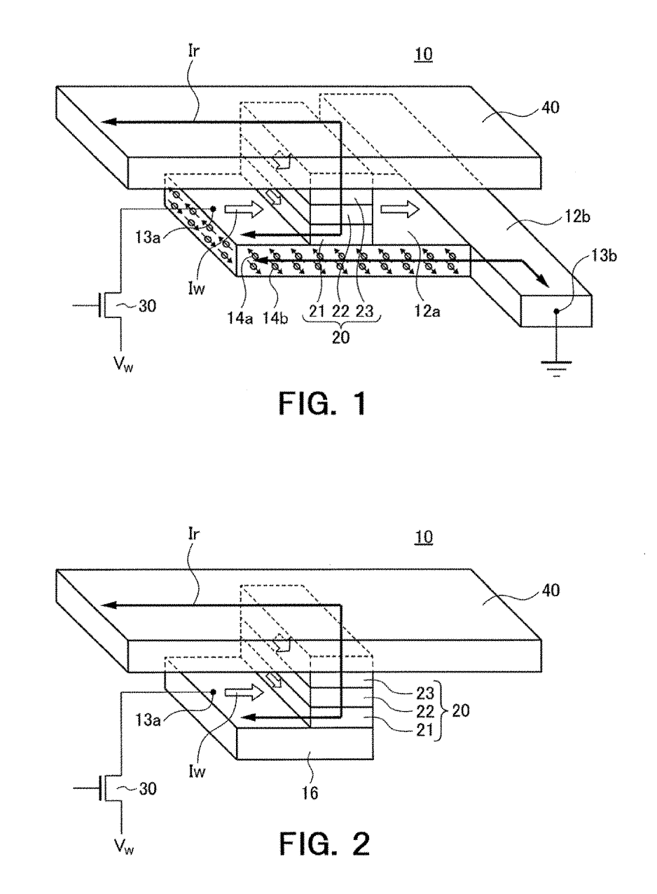

FIG. 1 shows an example of a SOT-MRAM memory cell. The memory cell includes nonmagnetic conductive layers (hereinafter also referred to as “SO layers”) 12a and 12b, a magnetoresistive element (for example, MTJ element) 20 to act as a memory element disposed on the conductive layer 12a, a switching element 30, and a wiring line 40. The conductive layer 12b is connected to the conductive layer 12a. The conductive layer 12a has a terminal 13a, and the conductive layer 12b has a terminal 13b. The conductive layer 12b may be eliminated. In such a case, the terminal 13b is disposed to the conductive layer 12a, and the MTJ element 20 is disposed in a region of the conductive layer 12a between the terminal 13a and the terminal 13b. The conductive layers 12a and 12b are conductive nonmagnetic layers, which generate a spin current when a current flows through them to apply a spin orbit torque (SOT) to a storage layer of the MTJ element. Thus, the conductive layers 12a and 12b are conductive nonmagnetic layers for causing spin orbit torque. Although a transistor is used as the switching element 30 in FIG. 1, a switching element other than a transistor may also be used, if it is turned on or off based on a control signal.

The MTJ element 20 includes a storage layer 21 in which the magnetization direction is changeable, a reference layer 23 in which the magnetization direction is fixed, and a nonmagnetic insulating layer 22 disposed between the storage layer 21 and the reference layer 23. The feature “magnetization direction is changeable” means that the magnetization direction may be changed after a write operation, and the feature “magnetization direction is fixed” means that the magnetization direction is not changed after a write operation. The storage layer 21 is connected to the conductive layer 12a, and the reference layer 23 is connected to the wiring line 40. One (“terminal”) of the source and the drain of the transistor 30 is connected to the terminal 13a of the conductive layer 12a. The other (“terminal”) of the source and the drain of the transistor 30 and the gate (“control terminal”) are connected to a control circuit that is not shown. The terminal 13b of the conductive layer 12b is grounded as shown in FIG. 1, or connected to the control circuit. The control circuit is also connected to the wiring line 40.

In this SOT-MRAM, a write operation is performed by causing a write current Iw to flow through the conductive layers 12a and 12b between the terminal 13a and the terminal 13b, by means of the transistor 30, and a read operation is performed by causing a read current Ir to flow through the terminal 13a, the conductive layer 12a, the MTJ element 20, and the wiring line 40, by means of the transistor 30. Thus, as described above, the write current path and the read current path are different from each other.

FIG. 2 shows an example of a memory cell of a STT-MRAM. The memory cell incudes a wiring line 16, an MTJ element 20, and a wiring line 40. The MTJ element 20 is disposed between the wiring line 16 and the wiring line 40, and includes a storage layer 21, a reference layer 23, and a nonmagnetic insulating layer 22 disposed between the storage layer 21 and the reference layer 23. One of the storage layer 21 and the reference layer 23 is connected to the wiring line 16, and the other is connected to the wiring line 40. In FIG. 2, the storage layer 21 is connected to the wiring line 16, and the reference layer 23 is connected to the wiring line 40. In the STT-MRAM, a write operation is performed by causing a write current Iw to flow between the wiring line 16 and the wiring line 40 by means of the transistor 30, and a read operation is performed by causing a read current Iᵣ to flow between the wiring line 16 and the wiring line 40 by means of the transistor 30. Thus, the write current path is the same as the read current path.

As described above, the write efficiency of the SOT-MRAM is inferior to that of the STT-MRAM. Therefore, the write efficiency needs to be improved. The write efficiency is expressed by dividing Δ (=KV/(k_{B}T)), which is the index of the thermal stability, by I_{c}, i.e., Δ/I_{c}, where K is the uniaxial magnetic anisotropy of the storage layer, V is the volume of the storage layer, k_{B} is the Boltzmann constant, T is the absolute temperature of the storage layer, and KV is the height of the energy barrier in cases where the spin in the storage layer and the spin in the reference layer are in the parallel state and the antiparallel state. Assuming that the write current needed to change the magnetization direction of the storage layer from parallel to antiparallel relative to the magnetization direction of the reference layer is Iₚ, and the write current needed to change the magnetization direction of the storage layer from antiparallel to parallel relative to the magnetization direction of the reference layer is Iₐₚ, I_{c} is the mean value of Iₚ and Iₐₚ, i.e., I_{c}=(Iₚ+Iₐₚ)/2.

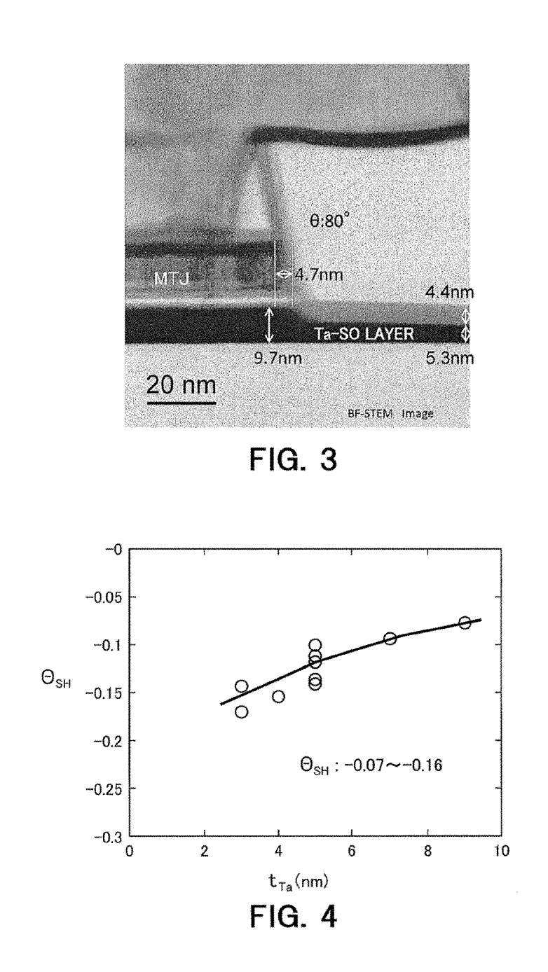

FIG. 3 is a photograph taken by a transmission electron microscope (TEM), showing a section near an MTJ element of a memory cell of an actually formed SOT-MRAM. The MTJ element of the memory cell is formed on a conductive layer (“SO layer”) of Ta having a thickness of 9.7 nm. As can be understood from FIG. 3, in a region which is not immediately below the MTJ element, and in which the conductive layer is in contact with the interlayer insulating film, the surface of the conductive layer is oxidized and the thickness is reduced from 9.7 nm to 5.3 nm. This means that the thickness of the oxidized portion of the conductive layer is 4.4 (=9.7−5.3) nm.

FIG. 4 shows the dependency of the spin Hall angle Θ_{SH} on the thickness of the conductive layer including a nonmagnetic heavy metal element. The conductive layer used for FIG. 4 is a β-Ta layer. The write current density Jc, which is obtained by dividing I_{c} by the cross-sectional area of the conductive layer, is proportional to the absolute value of the spin Hall angle θ_{SH}. Therefore, if, for example, the thickness t_{Ta} of the conductive layer is reduced from 10 nm to 6 nm, the write current mean value I_{c} decreases to 1/2.8. Accordingly, the thickness of the conductive layer may better be reduced in order to reduce the write current. However, as has been explained with reference to FIG. 3, if the thickness of the conductive layer is reduced to 6 nm, the thickness of the region of the conductive layer other than the MTJ element region becomes 1.6 (=6−4.4) nm. This causes the conductive layer to have a high resistance, and to lose the function of an electrode.

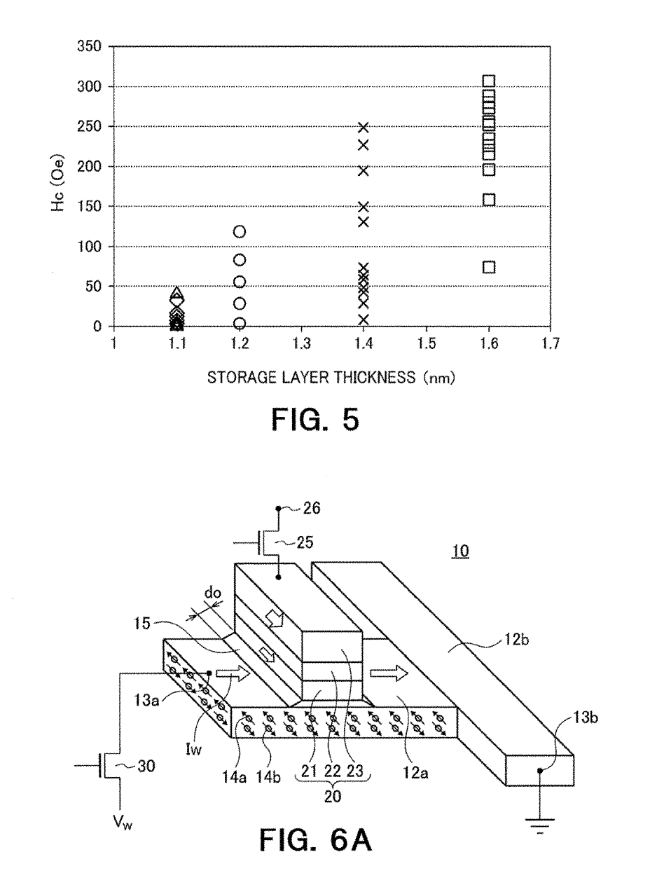

FIG. 5 shows a result of the measurement of the coercive force Hc of storage layers of CoFeB each included in an MTJ element, the storage layers having a thickness of 1.1 nm, 1.2 nm, 1.4 nm, and 1.6 nm, and formed on a conductive layer of β-Ta. As can be understood from FIG. 5, the coercive force Hc of the storage layer varies in each of the above samples. The reason for the variation is as follows.

An MTJ element including a CoFeB storage layer is generally formed on an amorphous layer. Therefore, the CoFeB layer grows as an amorphous layer. A nonmagnetic insulating layer of MgO is formed on the CoFeB layer to be (100)-oriented. Thereafter, due to the post annealing, CoFeB is uniformly oriented on the MgO(100) crystal surface. Therefore, the variation in the coercive force Hc is subtle.

However, the conductive layer underneath an MTJ element of a SOT-MRAM is a crystalline layer of, for example, β-Ta having a crystalline structure with great spin orbit torque in order to reduce the write current. Therefore, the CoFeB layer formed on the conductive layer is not a complete amorphous layer and grows in various directions. This leads to the variation in coercive force Hc. Another reason for the variation in coercive force Hc is a large absolute value of the magnetization, i.e., saturation magnetization Ms, of CoFeB, which is approximately equal to 1600 emu/cc even after the annealing at a temperature of 300° C. This causes B in CoFeB to be absorbed by β-Ta and diffused to the conductive layer.

In order to reduce the write current, a material having a large spin Hall angle Θ_{SH} is preferably used to form the conductive layer, as described above. Known materials having a large spin Hall angle Θ_{SH} include a metal such as Ta, W, Re, Os, Ir, Pt, Au, or Ag, an alloy containing at least one of the above elements, and an alloy of Cu and a material having 5 d electrons that cause great spin orbit scattering such as Cu—Bi.

It is reported that if a β-W layer is formed in an atmosphere including the noble gas Ar and oxygen, a maximum value at the present stage of the spin Hall angle Θ_{SH} is −0.5 (Nature Comm. DOI:10.1038/ncomms10644).

Next, a problem of the material of the conductive layer will be described. If a CoFeB monolayer film is formed on a β-W layer, and the spin Hall angle Θ_{SH} of this layer is evaluated by the ferromagnetic resonance method, Θ_{SH} of −0.5 may be obtained, as described above (Nature Comm. DOI:10.1038/ncomms10644). However, the characteristics of an MTJ element including a storage layer of CoFeB formed on the β-W layer are considerably degraded, and the MR characteristics of the CoFeB layer are also considerably degraded due to the generation of a nonmagnetic layer (dead layer) in the CoFeB layer after the annealing at a temperature of 300° C. In contrast, the characteristics of an MTJ element formed on a β-Ta layer have no problem. It has become apparent that the thickness of the nonmagnetic layer in the CoFeB layer is from 0.2 nm to 0.3 nm or more, and that the MR ratio of the CoFeB layer is reduced from about 200% to less than 50%. This is a great problem to be solved in achieving a large-capacity MRAM.

The inventors of the present invention have studied hard to obtain SOT-MRAMs that are capable of solving the above problem. Such SOT-MRAMs will be described in the descriptions of embodiments.

### First Embodiment

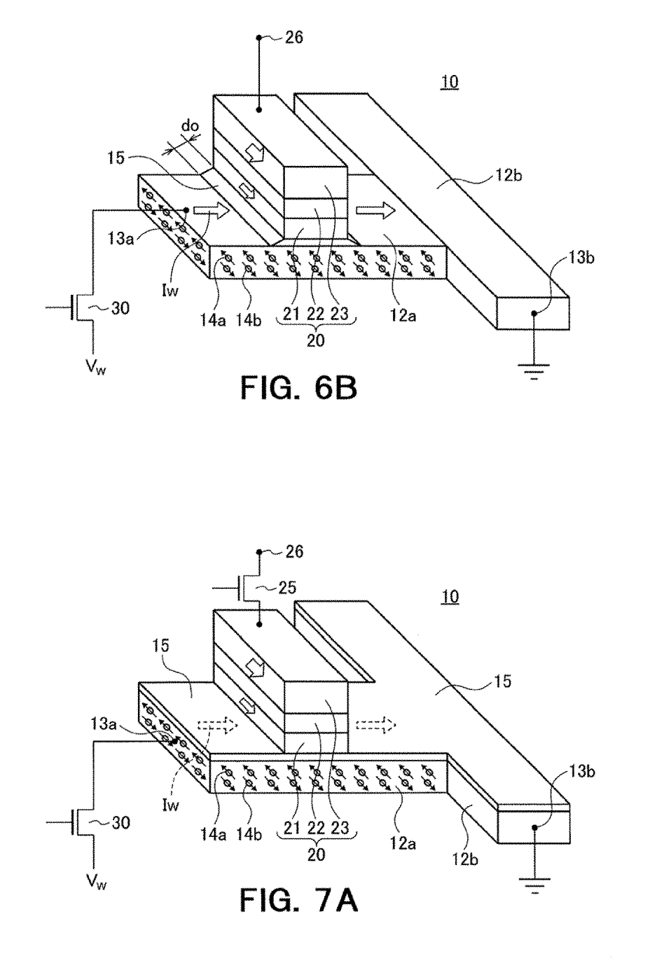

A magnetic memory according to a first embodiment will be described with reference to FIG. 6A. The magnetic memory according to the first embodiment is a SOT-MRAM including at least one memory cell. The memory cell is shown in FIG. 6A. The memory cell 10 includes conductive layers 12a and 12b, a layer 15 disposed on the conductive layer 12a, an MTJ element 20 disposed on the layer 15 on the conductive layer 12a, a switching element 25, and a switching element 30. The conductive layer 12b is connected to the conductive layer 12a. The conductive layer 12a has a terminal 13a, and the conductive layer 12b has a terminal 13b. The terminals 13a and 13b may be electrically connected to the conductive layers 12a and 12b, respectively. The terminals 13a and 13b are used to cause a current to flow through the conductive layers 12a and 12b. Although the switching elements 25 and 30 are transistors in FIG. 6A, they may be switching elements other than transistors as long as they turn on or off based on a control signal. In the following descriptions, the switching elements 25 and 30 are transistors.

The layer 15 is formed of an oxide or nitride containing at least one of Mg, Al, Si, Hf or a rare earth element. In other words, the layer 15 may be formed of an oxide or nitride of an alloy containing at least one of the aforementioned elements. As used herein, a phrase referring to “at least one of” a list of items refers to any combination of those items, including a single member. As an example, “at least one of: a, b, or c” is intended to cover a, b, c, a-b, a-c, b-c, and a-b-c.”

The MTJ element 20 includes a storage layer 21 in which the magnetization direction is changeable, a reference layer 23 in which the magnetization direction is fixed, and a nonmagnetic insulating layer 22 disposed between the storage layer 21 and the reference layer 23. The storage layer 21 is connected to the conductive layer 12a via the layer 15, and the reference layer 23 is connected to one of the source and the drain (“terminal”) of the transistor 25. The other of the source and the drain (“terminal”) of the transistor 25 is connected to a control circuit (not shown) via a third terminal 26, and the gate (“control terminal”) is also connected to the control circuit. The transistor 25 may be eliminated. In such a case, the control circuit controls the voltage applied to the reference layer 23 of the MTJ element 20 via the third terminal 26. The third terminal 26 is used to apply a voltage to and cause a current to flow through the MTJ element 20.

One of the source and the drain (“terminal”) of the transistor 30 is connected to the terminal 13a of the conductive layer 12a. The other of the source and the drain (“terminal”) and the gate (“control terminal”) of the transistor 30 are connected to a control circuit (not shown). The terminal 13b of the conductive layer 12b is grounded as shown in FIG. 6A or connected to the control circuit. A transistor may be disposed between the terminal 13b and the control circuit.

In the SOT-MRAM, a write operation is performed by applying a voltage to the reference layer 23 of the MTJ element 20 by means of the transistor 25 and causing a write current I_{w} to flow through the conductive layers 12a and 12b between the terminal 13a and the terminal 13b by means of the transistor 30. When the write current I_{w} flows through the conductive layer 12a, electrons 14a that are spin-polarized in one of the up spin direction and the down spin direction flow on the top surface side of the conductive layer 12a, and electrons 14b that are spin-polarized in the other of the up spin direction and the down spin direction flow on the lower surface side of the conductive layer 12a. This causes a spin current, which applies a spin torque to the storage layer 21 of the MTJ element 20, resulting in the switching of the magnetization direction of the storage layer 21. In the write operation, the voltage may be applied to the reference layer 23 of the MTJ element 20 by means of the transistor 25. The applied voltage changes the uniaxial magnetic anisotropy in the storage layer 21 of the MTJ element 20. This may facilitate the switching of the magnetization direction in the storage layer 21. The transistor 25 may be eliminated and the reference layer 23 of the MTJ element 20 may be electrically connected to a bit line (not shown) via the third terminal 26, as a first modification of the first embodiment shown in FIG. 6B.

A read operation is performed by causing a read current Iᵣ (not shown) to flow through the terminal 13a, the conductive layer 12a, the MTJ element 20, and the transistor 25 or the aforementioned bit line by means of the transistor 30. The control circuit includes a write circuit for performing the write operation and a readout circuit for performing the read operation.

In the first embodiment, the layer 15 is disposed immediately below the MTJ element 20 on the conductive layer 12a. If the layer 15 and the MTJ element 20 are projected upon the conductive layer 12a, the area of the layer 15 is greater than the area of the storage layer 21 of the MTJ element 20. Thus, the area of the surface of the layer 15 facing the conductive layer 12a is greater than the area of the surface of the storage layer 21 facing the layer 15. A distance d₀ between the side surface the layer 15 and the side surface of the storage layer 21 crossing the direction in which the write current Iw flows is preferably longer than the spin diffusion length. The spin diffusion length of heavy metals is short, from 0.5 nm to several nm, although the actual length may differ for each material. With the above-described structure, a more amount of spin may be absorbed from the conductive layer 12a to the storage layer 21.

In the magnetic memory according to the first embodiment containing the above-described structure including the layer 15 of an oxide or nitride disposed between the conductive layer 12a and the storage layer 21 of the MTJ element 20, the element diffusion between the storage layer 21 and the conductive layer 12a may be prevented. For example, if the storage layer 21 contains boron (B), the boron may be prevented from being diffused into and absorbed by the conductive layer 12a. This prevents the generation of a nonmagnetic layer that may eliminate the magnetization in the storage layer 21. Since the generation of the nonmagnetic layer may be prevented, the value of the write current may be reduced, and the variation in coercive force Hc may also be reduced. On the other hand, B (boron) needs to be eliminated from CoFeB to improve the magnetoresistance (MR). From this viewpoint, the storage layer may preferably have a multilayer structure including a nonmagnetic layer, by stacking a ferromagnetic layer, a nonmagnetic layer, and a ferromagnetic layer in this order.

An increase in the thickness of the layer 15 leads to a steep increase in the value of the write current. Therefore, the thickness of the layer 15 is preferably 1 nm or less, and more preferably 0.9 nm or less. The material of the layer 15 is preferably an oxide that may prevent the spin-polarized electrons in the conductive layer 12a of such materials as Ta, W, and Pt. Rare earth elements include magnetic elements with f electrons, which do not have an energy band on the Fermi surface, and thus have less spin scattering from the electrical viewpoint. Therefore, a preferable result may be obtained if the layer 15 includes an oxide or nitride of a rare earth element. On the contrary, it has been revealed that the use of a material of the conductive layer 12a such as an oxide or nitride of Ta or W in the layer 15 may lead to an unfavorable result.

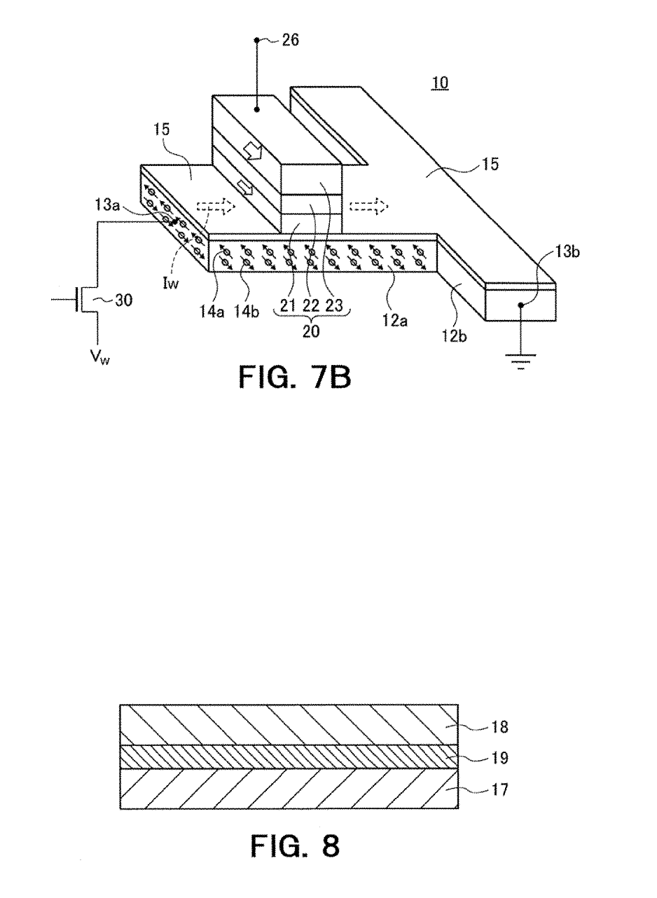

The layer 15 acts as an etching stopper when the MTJ element 20 is microfabricated. The layer 15 may be left on the conductive layer 12a as in a magnetic memory according to a second modification of the first embodiment shown in FIG. 7A by appropriately adjusting the etching time. The thickness of the conductive layer 12a may be decreased to reduce the value of the write current Ic if the layer 15 is left on the conductive layer 12a as in this modification. Therefore, the write efficiency may be improved. The transistor 25 of the second modification shown in FIG. 7A may be omitted, and the MTJ element 20 may be electrically connected to a bit line (not shown) as in the first modification shown in FIG. 6B. This is shown in FIG. 7B which is a perspective view of a magnetic memory according to a third modification of the first embodiment.

Even if the layer 15 is used as an etching stopper, the thickness of a region of the conductive layer 12a that is not covered by the layer 15 may be reduced as compared to the thickness of the other region that is covered by the layer 15 due to the etching or oxidation. In order to prevent an increase in resistance of the conductive layer 12a caused by the decrease in thickness, the difference between the thickness of the region of the conductive layer 12a covered by the layer 15 and the thickness of the region not covered by the layer 15 is preferably 2 nm or less, and more preferably 1 nm or less. Thus, the difference between the thickness of the conductive layer 12a immediately below the layer 15 and the thickness in the other region is preferably 2 nm or less, and more preferably 1 nm or less.

In the first embodiment, the layer 15 is disposed in a region of the conductive layer 12a including the region immediately below the MTJ element 20. Therefore, the conductive layer 12a in the first embodiment may be reduced as in the case of the second modification to reduce the value of the write current Ic, thereby improving the write efficiency. While a current is flowing through the conductive layer 12a, electrons with the up spin and electrons with the down spin are separated to the top surface side and the lower surface side of the conductive layer 12a due to the spin Hall effect. The spin of the electrons on the storage layer 21 side is absorbed by the storage layer 21, and thus the magnetization switching is achieved. The spin is absorbed by the storage layer 21 from not only the region immediately below the MTJ element 20 but also from the region around the MTJ element 20 in which spin is accumulated. Therefore, the state shown in FIG. 3, in which the conductive layer 12a is oxidized in the region around the MTJ element 20, is not preferable to reduce the write current Ic, and to improve the write efficiency. The reason why the variation in coercive force Hc is reduced in the first embodiment and its modifications is considered to be that the presence of the layer 15 between the conductive layer 12a and the MTJ element 20 helps the amorphous growth of CoFeB, and prevents a great amount of boron (B) atoms from being diffused into the conductive layer 12a during the post annealing.

As described above, the first embodiment and its modifications are capable of improving the current density of the write current flowing through the conductive layer 12a, thereby improving the write efficiency. Furthermore, the first embodiment and its modifications are also capable of reducing the variation in coercive force Hc. Since the layer 15 acts as an etching stopper of the conductive layer 12a, a magnetic memory with a thin conductive layer may be provided.

The magnetic material of the storage layer 21 and the reference layer 23 of the first embodiment is not limited, and may be a Ni—Fe alloy, a Co—Fe alloy or a Co—Fe—Ni alloy. An amorphous material such as (Co, Fe)—(B), (Co, Fe, Ni)—(B), (Co, Fe, Ni)—(B)—(P, Al, Mo, Nb, Mn), or Co—(Zr, Hf, Nb, Ta, Ti) may also be used. For example, (Co, Fe, Ni) means that at least rye of Co, Fe, or Ni is included in the material. Furthermore, (B) means that B may be included or not included.

The magnetic material of the storage layer 21 and the reference layer 23 may also be a Heusler material such as Co—Fe—Al, Co—Fe—Si, Co—Fe—Al—Si, Co—Mn—Si, or Co—Mn—Fe—Si. These layers preferably have a multilayer structure in which a plurality of magnetic layers are stacked, instead of a monolayer structure. In this case, for example, a nonmagnetic layer 19 is disposed between magnetic layers 17 and 18 as shown in FIG. 8, and the magnetic layers 17 and 18 are magnetically coupled over the nonmagnetic layer 19 by, for example, antiferromagnetic coupling or ferromagnetic coupling. If the storage layer 21 has in-plane magnetization, the magnetic coupling is preferably antiferromagnetic coupling in order to reduce the influence of the stray magnetic field.

In particular, the storage layer 21 preferably has a multilayer structure. If the magnetization direction (spin) is in parallel with the film plane, the preferable combinations of the multilayer structure include CoFe(B)/Cu/CoFe(B), Fe(CoB)/Cr/Fe(CoB), Mn-based Heusler/MgO/Mn-based Heusler, or a face-centered cubic (fcc) magnetic material/Ru/fcc magnetic material/(Ta, W, Mo)/CoFeB, CoFe/Cr/CoFe/(Ta, N, Mo)/CoFeB, CoFe/Cu/CoFe/(Ta, N, Mo)/CoFeB.

If the spin is perpendicular to the film plane, preferable combinations include Co(Fe)(B)/Pt/Co(Fe)(B), Co(Fe)(B)/Pd/Co(Fe)(B), Co(Fe)(B)/Ni/Co(Fe)(B), and fcc magnetic material (multilayer film) such as (Co/Pt)n/Ru/(Co/Pt)m/Ru/fcc magnetic material (multilayer film)/(Ta, W, Mo)/CoFeB. In the above multilayer m and n represent the number of stacked layers. For example, (Co/Pt)n means that Co/Pt are stacked n times. Instead of Pt, Pd may be used. If the fcc magnetic material (multilayer film) is used, an ultrathin (Ta, W, Mo)/CoFeB film is preferably disposed at the interface with the nonmagnetic insulating layer 22.

In a magnetic memory including multi-bit memory cells each including a plurality of MTJ elements like a magnetic memory according to a second embodiment that will be described later, the margin of the voltage applied to each MTJ element to cause a current to flow through the conductive layer to switch the spin of the storage layer of the MTJ element may be increased. If the polarity of a voltage applied to a plurality of MTJ elements is set to be different from that of a voltage applied to the other MTJ elements in the second embodiment, for example, if a voltage +V is applied to the former and a voltage −V is applied to the latter, and the spin of the storage layers included in the MTJ elements to which the voltage −V is applied is reversed, the margin may further be increased. The effect of increasing the margin is obtained by either or both of the change in magnetic anisotropy and the spin transfer torque magnetization switching assisted by the voltage applied to the MTJ element. From the viewpoint of power consumption, the change in magnetic anisotropy caused by increasing the resistance of the MTJ element when the voltage is applied is preferable. However, this also has a disadvantage that the read speed is decreased.

On the other hand, if the resistance of the MTJ element is reduced, the contribution of the voltage to the spin transfer torque magnetization switching increases to improve the read speed. However, the power consumption is increased as compared to the case where the magnetic anisotropy is changed by applying the voltage. Which assistance effect of the voltage, the change in magnetic anisotropy and the spin transfer torque magnetization switching, is used may be selected depending on the memory design, and at which value the resistance of the MTJ element needs to be set. The margin can be increased further if the storage layer of each MTJ element has a multilayer structure in the magnetic memory according to the second embodiment.

The reference layer 23 preferably has one-directional anisotropy, and the storage layer 21 preferably has uniaxial anisotropy. The thickness of these layers is preferably from 0.1 nm to 100 nm. Since these magnetic layers should not be superparamagnetic, the thickness is more preferably 0.4 nm or more.

A nonmagnetic element such as Ag (silver), Cu (copper), Au (gold), Al (aluminum), Mg (magnesium), Si (silicon), Bi (bismuth), Ta (tantalum), B (boron), C (carbon), O (oxygen), N (nitrogen), Pd (palladium), Pt (platinum), Zr (zirconium), Ir (iridium), W (tungsten), Mo (molybdenum), or Nb (niobium) may be added to the magnetic material of these layers to adjust the magnetic characteristics, the crystallinity, the mechanical characteristics, and the chemical characteristics.

The magnetic layer that is close to the nonmagnetic insulating layer 22 is preferably formed of such materials as Co—Fe, Co—Fe—Ni, Fe-rich Ni—Fe which have a large MR (magnetoresistance), and the magnetic layer that is not in contact with the nonmagnetic insulating layer 22 is preferably formed of Ni-rich Ni—Fe or Ni-rich Ni—Fe—Co to adjust the switching magnetic field with the large MR being maintained.

The material of the nonmagnetic insulating layer 22 is preferably an oxide such as AlOx, MgO, and Mg—AlOx.

The material of the conductive layer 12a is preferably a metal including a nonmagnetic heavy metal element with one or more outer shell electrons that are 5 d or greater electrons. For example, the material is preferably a metal selected from Ta, W, Re, Os, Ir, Pt, Au, and Ag, an alloy containing at least one of the above metals, or Cu—Bi.

The conductive layer 12a may have a multilayer structure including two or more layers. In this case, the electric resistance of a layer that is close to the storage layer is preferably low. Since the low electric resistance increases the amount of current flowing immediately below the MTJ element, the write current may become lower than that in the case where the electric resistance of the layer close to the storage layer is high. If the conductive layer 12a includes two layers, the layer that is more distant from the storage layer may include at least one of Hf, Al, Mg, or Ti, and B besides the above elements. The layer that is closer to the storage layer preferably includes a metal selected from Ta, W, Re, Os, Ir, Pt, Au, and Ag an alloy containing at least one of the above metals, or Cu—Si.

The material of the layer 15 is preferably selected from Mg, Al, Si, and Hf, or a rare earth element, or an oxide or nitride of an alloy of the above elements. More specifically, the layer 15 is preferably formed of a material such as magnesium oxide (MgO), aluminum nitride (AlN), aluminum oxide (AlOx), silicon nitride (SiN), silicon oxide (SiOx), hafnium oxide (HfOx), and an oxide or nitride of La, Ce, Pr, Nd, Pm, Sm, Eu, Gd, Tb, Dy, Ho, Er, Tm, and Yb. In the above chemical formula, “x” represents the composition ratio. The compositions of the above materials do not need to be completely accurate from the stoichiometric point of view, but may lack or additionally include, for example, oxygen or nitrogen. Thus, the layer 15 includes at least one of Mg, Al, Si, Hf, or a rare earth element, and at least one of oxygen or nitrogen.

The thickness of the nonmagnetic insulating layer 22 is preferably thin enough to allow a tunneling current to flow. However, if the coercive force (i.e., the magnetic anisotropy) of the storage layer of the MTJ element needs to be changed by means of the voltage as in the second embodiment that will be described later, the sheet resistance RA should not be too low, and is preferably a few tens Ωμm² to a few thousands KΩμm². In this case, if the sheet resistance is a few thousands KΩμm², the magnetization switching in the storage layer is mainly caused by the voltage control and the write operation through the conductive layer, and if the sheet resistance is a few tens Ωμm², the magnetization switching of the storage layer is mainly caused by a combination of the voltage control, the SOT write operation and the STT write operation.

The material of the reference layer 23 is not particularly limited, as long as the magnetization of this layer is stably fixed in one direction. In order to fix the magnetization of the magnetic layer in one direction, a multilayer structure including a plurality of stacked magnetic layers is used. More specifically, multilayer structures such as Co(Co—Fe)/Ru (ruthenium)/Co(Co—Fe), Co(Co—Fe)/Rh (rhodium)/Co(Co—Fe), Co(Co—Fe)/Ir (iridium)/Co(Co—Fe), Co(Co—Fe)/Os (osmium)/Co(Co—Fe), Co(Co—Fe)/Re (rhenium)/Co(Co—Fe), amorphous material such as Co—Fe—B/Ru (ruthenium)/Co—Fe, amorphous material such as Co—Fe—B/Ir (iridium)/Co—Fe, amorphous material such as Co—Fe—B/Os (osmium)/Co—Fe, or amorphous material such as Co—Fe—B/Re (rhenium)/Co—Fe are used.

Furthermore, a three-layer structure in which three magnetic layers are stacked may also be used, such as (Co/Pt)n/Ru/(Co/Pt)m/(Ta, W, Mo)/CoFeB, (Co/Pt)n/Ir/(Co/Pt)m/(Ta, W, Mo)/CoFeB, (Co/Pt)n/Re/(Co/Pt)m/(Ta, W, Mo)/CoFeB, or (Co/Pt)n/Rh/(Co/Pt)m/(Ta, W, Mo)/CoFeB. In the above three-layer combinations, m and n represent the number of stacked layers. For example, (Co/Pt)n means that Co/Pt are stacked n times. Instead of Pt, Pd may be used.

An antiferromagnetic layer may further be disposed to be adjacent to the reference layer having the multilayer structure. The material of the antiferromagnetic layer may be Fe—Mn, Pt—Mn, Pt—Cr—Mn, Ni—Mn, Ir—Mn, NiO, and Fe₂O₃. The structure with an antiferromagnetic layer may prevent the magnetization of the reference layer from being influenced by a current magnetic field from a bit line or word line. Therefore, the magnetization of the reference layer is securely fixed. Furthermore, a stray field from the reference layer may be reduced, and the magnetization shift of the storage layer may be adjusted by changing the thicknesses of the two magnetic layers of the reference layer. A preferable thickness of each magnetic layer is 0.4 nm or more, and not be the thickness which the magnetic layer becomes superparamagnetic.

### Second Embodiment

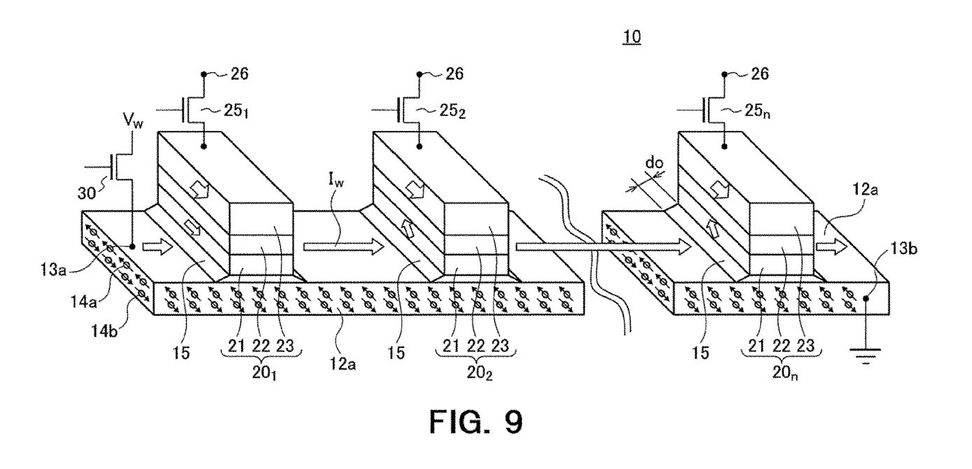

A magnetic memory according to a second embodiment will be described with reference to FIG. 9. The magnetic memory according to the second embodiment includes at least one memory cell, which is shown in FIG. 9. The memory cell 10 according to the second embodiment includes a conductive layer 12a, n (n≧2) MTJ elements 20₁ to 20ₙ, n transistors 25₁ to 25ₙ, and a transistor 30.

The conductive layer 12a has terminals 13a and 13b. The n MTJ elements 20₁ to 20ₙ are disposed to be separate from each other on a region of the conductive layer 12a between the terminal 13a and the terminal 13b. Each of the MTJ elements 20₁ to 20ₙ includes a reference layer 23 disposed above the conductive layer 12a, a storage layer 21 disposed between the reference layer 23 and the conductive layer 12a, and a nonmagnetic insulating layer 22 disposed between the storage layer 21 and the reference layer 23. Each Mn element 20ᵢ (i=1, . . . , n) is a memory element for storing one bit, and each memory cell is a 1-byte cell including n bits. The material of each of the constituent elements of the second embodiment is the same as that of the first embodiment. The memory cell may include a dummy memory element (for example an MTJ element) that is not used as a memory element.

One of the source and the drain of the transistor 25ᵢ is connected to the reference layer 23 of the MTJ element 20i (i=1, . . . , n), and the other is connected to a third terminal 26. One of the source and the drain of the transistor 30 is connected to the terminal 13a, and the other is connected to a control circuit (not shown). The transistor 25ᵢ connected to the reference layer 23 of the MTJ element 20ᵢ (i=1, n) may be omitted, as in the first modification of the first embodiment shown in FIG. 6B. In this case, the reference layer 23 of the MTJ element 20ᵢ (i=1, . . . , n) is connected to a control circuit (not shown) via the third terminal 26 and a wiring line (bit line) that is not shown.

A layer 15 is disposed between the storage layer 21 of each of the MTJ elements 20₁ to 20 and the conductive layer 12a in the second embodiment, like the first embodiment shown in FIG. 6A. The layer 15 may be formed of an oxide or nitride containing at least one of Mg, Al, Si, Hf or a rare earth element. Thus, the layer 15 may be formed of an oxide or nitride of an alloy containing at least one of the above elements.

As in the first embodiment, the layer 15 of the second embodiment is disposed on a region of the conductive layer 12a including a region immediately below each MTJ element 20i (i=1, . . . , n). When viewed from above, the plane area of the layer 15 is greater than the plane area of the storage layer 21 of the MTJ element 20. The distance d₀ between the side surface of the layer 15 and the side surface of the storage layer 21 that cross the direction in which a write current I_{w} flows is preferably shorter than the spin diffusion length.

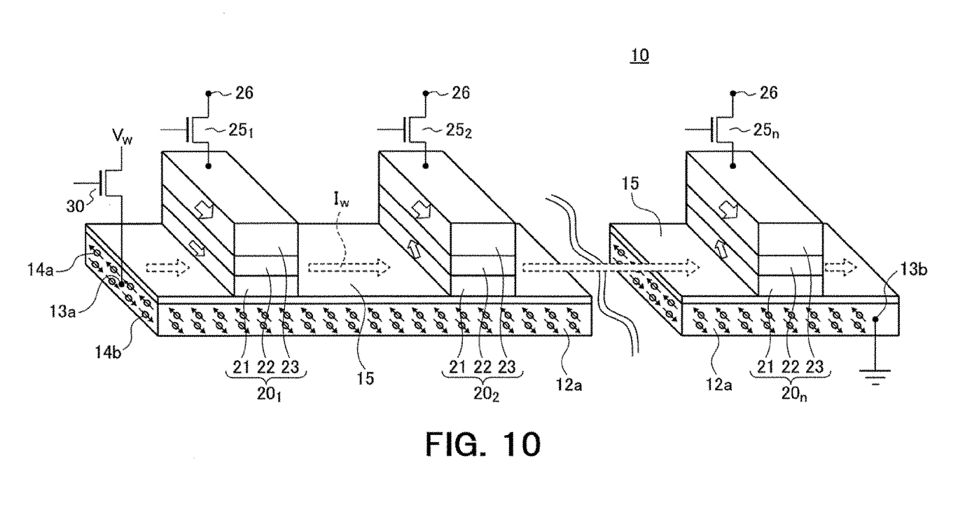

The layer 15 may be disposed to cover the top surface of the conductive layer 12a, as in a modification of the second embodiment shown in FIG. 10. The layer 15 does not need to cover the entire top surface of the conductive layer 12a as long as it covers the top surface of the conductive layer 12a in regions between adjacent MTJ elements in the magnetic memory according to the second embodiment. The transistor 25ᵢ connected to the reference layer 23 of the MTJ element 20ᵢ (i=1, . . . , n) may be eliminated as in the third modification of the first embodiment shown in FIG. 7B. In this case, the reference layer 23 of the MTJ element 20ᵢ (i=1, . . . , n) is connected to a control circuit via a wiring line (bit line).

### (Write Method)

A first write method used for the memory cell 10 will be described below. In this embodiment, a write operation for the memory cell 10 is performed in two stages. A write operation for writing 1-byte data (0, 1, 0, 0, . . . , 0, 1) to the memory cell 10 is taken as an example. In this write operation, data “1” is written to the MTJ elements 20₂ and 20ₙ, and data “0” is written to the other MTJ elements.

First, the transistor 30 and the transistors 25₁ to 25ₙ are turned on by means of the control circuit that is not shown to apply a first potential (for example a positive potential) the reference layers 23 of the MTJ elements 20₁ to 20ₙ, and to cause a write current I_{w} to flow between the terminal 13a and the terminal 13b of the conductive layer 12a. At this time, the magnetization stability (uniaxial magnetic anisotropy) of the storage layers 21 of all the MTJ elements 20₁ to 20ₙ is weakened, and the threshold current of the storage layers changes from I_{c} to I_{ch}. For example, the threshold current I_{ch}is selected to be I_{c}/2, by applying a voltage to the reference layer of the MTJ element to lower the uniaxial magnetic anisotropy. In this state, a write current I_{w0} (I_{w}>I_{w0}>I_{ch}) is caused to flow through the conductive layer 12a to write data “0” to all of the MTJ elements 20₁ to 20ₙ (0, 0, 0, 0, . . . , 0, 0). Generally, a write error rate of about 10⁻¹¹ may be obtained if a write current with a value about 1.5 times the value of the threshold current I_{ch} is caused to flow. Therefore, the write current I_{w0} is approximately equal to 1.5 times the threshold current I_{ch}.

Next, the transistors of the bits that should be “1”, for example the transistors 25₂ and 25ₙ, are turned on by means of the control circuit that is not shown to apply a second potential (for example a positive potential) to the reference layers 23 of the MTJ elements 20₂ and 20ₙ. At this time, the transistor 30 is also turned on by means of the control circuit that is not shown to cause a write current I_{w1} (I_{c}>I_{w1}>I_{ch}) to flow through the conductive layer 12a in a direction that is opposite to the direction for writing data “0”. As a result, data “1” is written to the storage layers 21 of the MTJ elements 20₂ and 25₈. The write current I_{w1} is approximately equal to 1.5 times the threshold current I_{ch}, like the aforementioned case. Thus, 1-byte data (0, 1, 0, 0, . . . , 0, 1) can be written by the two-stage write operation, the two-stage write operation is performed by the control circuit that is not shown, which includes a first write circuit for performing the first-stage write operation and a second write circuit for performing the second-stage write operation.

The above-described first write method is performed by applying a first potential (for example a positive potential) to the reference layers 23 of the MTJ elements 20₁ to 20ₙ and causing a first write current to flow between the terminal 13a and the terminal 13b of the conductive layer 12a, and then by applying a second potential to the reference layers of some of the MTJ elements among the MTJ elements 20₁ to 20ₙ, to which data is written, and by causing a second write current to flow in a direction that is opposite to the direction of the first write current between the terminal 13a and the terminal 13b of the conductive layer 12a.

A second write method, which is different from the first write method, may also be used. Like the first write method, the second write method is performed in two stages. First, two types of potentials are applied to the MTJ elements 20₁ to 20ₙ to make easy-to-write bits and difficult-to-write bits. For example, a positive potential Va is applied to activation bits (MTJ elements) 20₂ to 20ₙ via the corresponding transistors 25₂ to 25ₙ, and a negative potential Vp is applied to an inactivation bit (MTJ element) 20₁ via the corresponding transistor 25₁. A write current is caused to flow through the conductive layer 12a from the first terminal 13a to the second terminal 13b, for example. As a result, data “0” is written to the activation bits (MTJ elements) 20₂ to 20ₙ. Thereafter, a positive potential Va is applied to the MTJ element 20₁ via the transistor 25₁, and a negative potential Vp is applied to the MTJ elements 20₂ to 20ₙ via the transistors 25 to 25ₙ, and a write current is caused to flow from the second terminal 13b to the first terminal 13a of the conductive layer 12a. As a result, data “1” is written to the MTJ element 20₁.

The second write method is performed by applying a first potential to the reference layers of the magnetoresistive elements in a first group in the magnetoresistive elements 20₁ to 20n and a second potential that is different from the first potential to the reference layers of the magnetoresistive elements in a second group that is different from the first group in the magnetoresistive elements 20₁ to 20ₙ, causing a first write current to flow between the first terminal 13a and the second terminal 13b, and applying the second potential to the reference layers of the magnetoresistive elements in the first group and the first potential to the reference layers of the magnetoresistive elements in the second group and causing a second write current to flow in a direction opposite to the direction of the first write current between the first terminal 13a and the second terminal 13b.

An operation for reading data from the memory cell 10 is performed by turning on the transistor 30 and the transistors 25₁ to 25ₙ and measuring the resistance of a selected bit by means of a current flowing through the transistors 25₁ to 25ₙ, thereby determining the contents of data.

The MTJ element may be selected to write data to it easily. On the contrary, the MTJ element may be selected to increase the uniaxial magnetic anisotropy to make it difficult to write data to it. For example, a negative potential is applied to the reference layer 23 of the selected MTJ element to make it difficult to write data to it. In this case, data is written only to the non-selected MTJ elements.

The presence of the layer 15 disposed between the MTJ element and the conductive layer 12a in the second embodiment improves the current density of the write current, thereby improving the write efficiency as in the first embodiment. Furthermore, the variation in coercive force Hc is reduced. Since the layer 15 acts as an etching stopper of the conductive layer 12a, a magnetic memory with a thin conductive layer may be provided.

In the first and second embodiments and their modifications, the longitudinal direction of the MTJ elements is substantially perpendicular to the direction of the current flowing through the conductive layer 12a. If the magnetization direction in the storage layer or the reference layer is the vertical direction, the aspect ratio of the MTJ element does not need to be changed. If the magnetization direction is parallel to the plane, the longitudinal direction of the MTJ element may be inclined relative to the direction of the current flowing through the conductive layer 12a. If the inclined angle e is more than 30 degrees and less than 90 degrees, the write current may be reduced, which is an advantageous effect. If the inclined angle θ is more than 0 degree and less than 30, the write speed may be improved although the write current may not be reduced considerably. Therefore, in any case, the power consumption may be reduced.

Assuming that the minimum feature size is represented by “F” in the first embodiment and its modifications, the size of a memory cell is represented by “12F².” In the second embodiment and its modification, however, the size of a memory cell may be reduced to 6F². Thus, the area occupied by the memory cells may be reduced as compared with that of the first embodiment and its modifications.

Although an MTJ element is used as the memory element in the first and second embodiments and their modifications, a magnetoresistive element in which the nonmagnetic insulating layer 22 is a nonmagnetic metal layer may also be used.

### Examples

Hereinafter, the embodiments will be described further with reference to some examples.

### First Example

Samples 1 to 14, which are memory cells according to the first embodiment shown in FIG. 6A with the material of the layer 15 being changed, are prepared to be used in a magnetic memory according to a first example. The samples are annealed at a temperature of 300° C. The storage layer 21 of the MTJ element 20 is formed of CoFeB, the nonmagnetic insulating layer 22 is formed of MgO, and the reference layer 23 is formed of CoFe.

Sample 1 includes a β-Ta conductive layer (SO layer) 12a with a thickness of 6.0 nm. No layer 15 is provided to Sample 1. Sample 2 includes a W conductive layer 12a having a thickness of 6.0 nm. No layer 15 is provided to Sample 2.

Sample 3 includes a β-Ta conductive layer 12a with a thickness of 6.0 nm. A layer 15 of MgOx with a thickness of 0.95 nm is provided to Sample 3.

Sample 4 includes a β-Ta conductive layer 12a with a thickness of 6.0 nm. A layer 15 of AlOx with a thickness of 0.9 nm is provided to Sample 4.

Sample 5 includes a β-Ta conductive layer 12a with a thickness of 6.0 nm. A layer 15 of SiN with a thickness of 0.95 nm is provided to Sample 5.

Sample 6 includes a β-Ta conductive layer 12a with a thickness of 6.0 nm. A layer 15 of HfOx with a thickness of 0.98 nm is provided to Sample 6.

Sample 7 includes a β-Ta conductive layer 12a with a thickness of 6.0 nm. A layer 15 of GdOx with a thickness of 0.95 nm is provided to Sample 7.

Sample 8 includes a β-Ta conductive layer 12a with a thickness of 6.0 nm. A layer 15 of ErOx with a thickness of 0.98 nm is provided to Sample 8.

Sample 9 includes a β-W conductive layer 12a with a thickness of 6.0 nm. A layer 15 of MgOx with a thickness of 0.9 nm is provided to Sample 9.

Sample 10 includes a β-W conductive layer 12a with a thickness of 6.0 nm. A layer 15 of AlOx with a thickness of 0.93 nm is provided to Sample 10.

Sample 11 includes a β-W conductive layer 12a with a thickness of 6.0 nm. A layer 15 of SiN with a thickness of 0.9 nm is provided to Sample 11.

Sample 12 includes a β-W conductive layer 12a with a thickness of 6.0 nm. A layer 15 of HfOx with a thickness of 0.92 nm is provided to Sample 12.

Sample 13 includes a β-W conductive layer 12a with a thickness of 6.0 nm. A layer 15 of GdOx with a thickness of 0.95 nm is provided to Sample 13.

Sample 14 includes a β-W conductive layer 12a with a thickness of 6.0 nm. A layer 15 of ErOx with a thickness of 0.96 nm is provided to Sample 14.

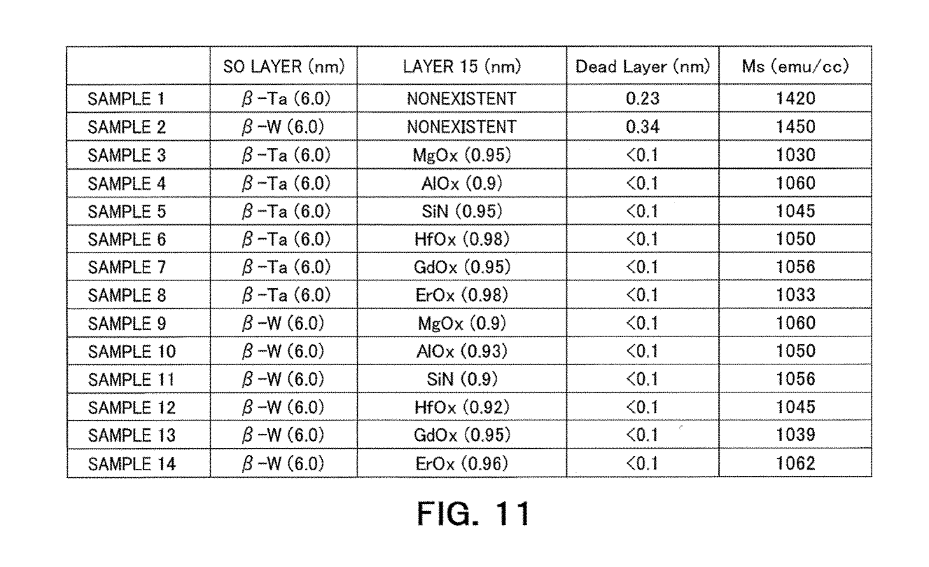

FIG. 11 shows the result of measuring the thickness of the nonmagnetic layer (dead layer) appearing in the storage layer 21 of CoFeB and the saturation magnetization Ms of the storage layer 21 in Samples 1 to 14. As can be understood from FIG. 11, the layer 15 disposed between the MTJ element and the conductive layer 12a allows a reduction in the thickness of the nonmagnetic layer (dead layer) generated in the storage layer 21 of CoFeB to less than 0.1 nm. This prevents the degradation in the magnetoresistance characteristics. The saturation magnetization of Samples 3 to 14 with the layer 15 is less than that of Samples 1 and 2 without the layer 15.

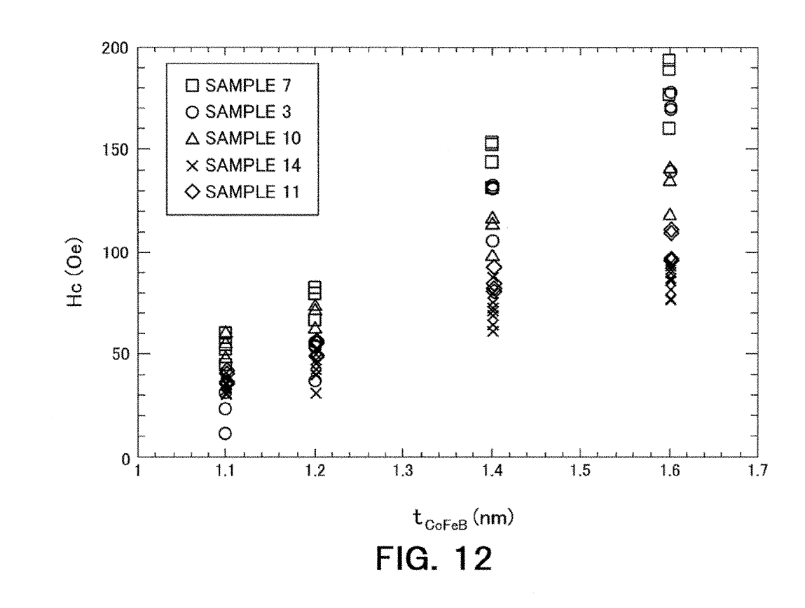

FIG. 12 shows a result of the measurement of coercive force in the cases where the thickness of the storage layer 21 of CoFeB is 1.1 nm, 1.2 nm, 1.4 nm, or 1.6 nm in Samples 3, 7, 10, 11, and 14. The size of each sample is the same as the sample explained with reference to FIG. 5, i.e., 60 nm×180 nm. As can be understood from FIG. 12, the variation in the coercive force Hc in the samples with the layer 15 is less than that in the samples shown in FIG. 5.

### Second Example

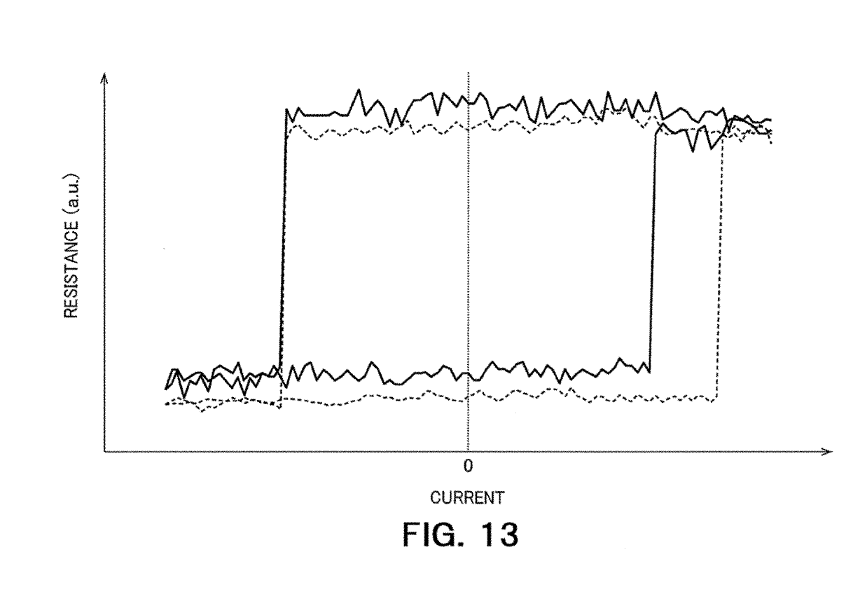

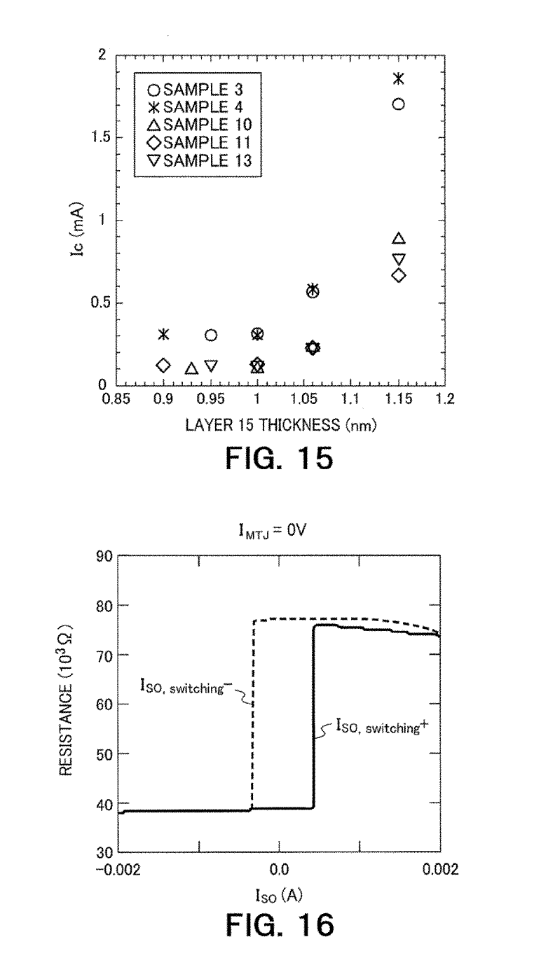

A second example will be described below. MTJ elements are prepared, which are the same as Samples 1 to 14 of the first example except for the storage layer of CoFeB that has a thickness of 1.2 nm. A write operation is performed on each MTJ element with a current caused to flow through the conductive layer (SO layer). FIG. 13 shows an evaluation result for Sample 3 with the layer 15 and Sample 1 without the layer 15. The lateral axis of FIG. 13 represents the current flowing through the SO layer and the longitudinal axis represents the resistance. The solid line in FIG. 15 indicates the result of Sample 3 with the layer 15, and the broken line indicates the result of Sample 1 without the layer 15. The width of the SO layer in each sample is 600 nm.

As can be understood from FIG. 13, the write current of Sample 3 with the layer 15 is lower than Sample 1 without the layer 15.

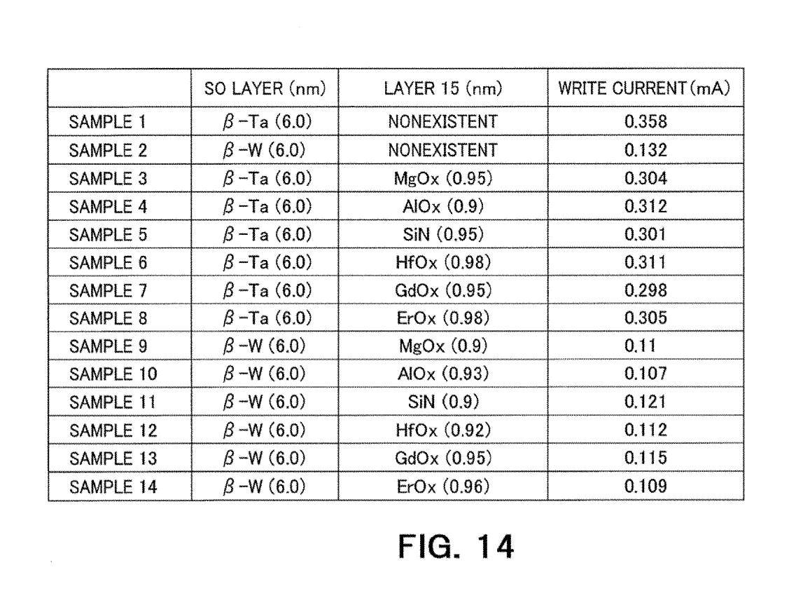

FIG. 14 shows the result of measurement of the write current flowing through the MTJ element of each of Samples 1 to 14. The write current in FIG. 14 is a write current Ic having a mean value of five MTJ elements included in the same sample. As can be understood from FIG. 14, the write current Ic of a sample with the layer 15 is obviously lower than another sample without the layer 15, if the SO layer is formed of the same material. The reason for this is considered to correlate to a decrease in the nonmagnetic layer (dead layer) generated in the storage layer, and the improvement in the spin absorption efficiency.

### Third Example

A third example will be described. MTJ elements are prepared, which are the same as Samples 3, 4, 10, 11, and 13 of the first example except for the storage layer of CoFeB that has a thickness of 1.2 nm and the layer 15 that has various thickness. A write operation test is performed on each MTJ element with a current caused to flow through the conductive layer (SO layer). FIG. 15 shows the revaluation result of the dependency of the write current Ic on the thickness of the layer 15.

As can be understood from FIG. 15, the write current rapidly increases if the thickness of the layer 15 is increased to 1.15 nm. Therefore, the thickness of the layer 15 is preferably 1 nm or less, and more preferably 0.9 nm or less.

### Fourth Example

A magnetic memory according to a fourth example is prepared, which includes memory cells according to the second embodiment shown in FIG. 9. Each memory cell of the fourth example includes, for example, four MTJ elements 20 that are disposed on a conductive layer 12a. The conductive layer 12a is formed of Ta with a thickness of 10 nm and a width (the dimension in the direction crossing the direction of the write current) of 600 nm. The storage layer 21 of each MTJ element 20 in each memory cell has in-plane magnetization, and has a monolayer or a multilayer structure. The storage layer 21 having a monolayer structure is formed of CoFeB having a thickness of 1.2 nm. There are three types of storage layer 21 having a multilayer structure. For example, a first multilayer structure are represented by CoFeB(1.2)/Cu/CoFeB(1.2), a second multilayer structure is represented by FeB(1.2)/Cr/FeB(1.2), and a third multilayer structure is represented by NiFe(1.2)/Ru/NiFe(0.8)/Ta(0.3)/CoFeB(0.8). Each number in parentheses indicates the thickness (nm) of the corresponding layer. For example, CoFeB(1.2) means that the thickness of CoFe is 1.2 nm.

FIG. 16 shows the magnetization switching characteristics of the storage layer in the MTJ element of one of the memory cells when the voltage applied to the reference layer 23 of the MTJ element of is 0V. The lateral axis indicates a current I_{SO} flowing through the conductive layer 12a, and the longitudinal axis indicates the resistance value of the MTJ element. The magnetization switching characteristic represented by a solid line in FIG. 16 indicates a current I_{SO, switching+} flowing in a positive direction that corresponds to a direction of the write current Iw indicated by an arrow in FIG. 9, and the magnetization switching characteristic represented by a broken line indicates a current I_{SO, switching-} flowing in a negative direction that is opposite to the positive direction.

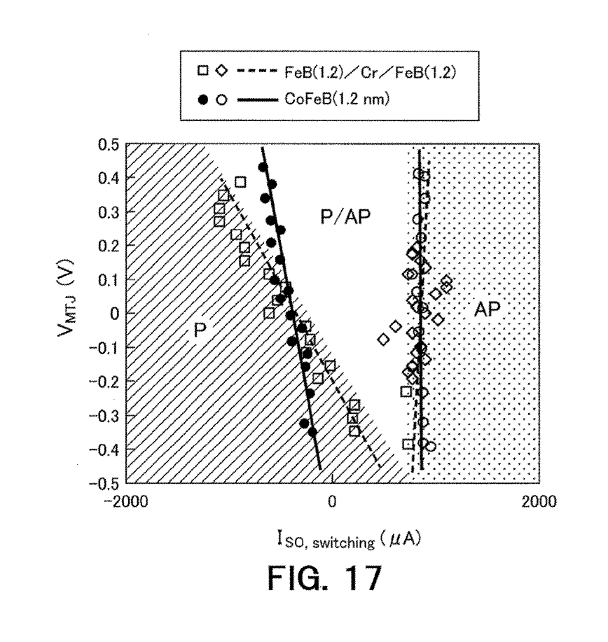

FIG. 17 shows the relationship between the voltage applied to the MTJ element and the current value I_{SO, switching} flowing through the conductive layer 12a, by which the magnetization switching is observed in each memory cell. The longitudinal axis of FIG. 17 indicates a voltage V_{MTJ} that is applied to an MTJ element of a memory cell including a storage layer 21 of CoFeB having a monolayer structure with a thickness of 1.2 nm, and to an MTJ element of a memory cell including a storage layer 21 having a multilayer structure of FeB(1.2)/Cr/FeB(1.2), and the lateral axis indicates a current value I_{SO, switching} caused to flow through a conductive layer 12a of each memory cell, by which the magnetization switching is observed.

The region represented by “P” in FIG. 17 indicates that the magnetization direction of the storage layer 21 and the magnetization direction of the reference layer 23 are in a parallel state in all of the MTJ elements in the memory cell, the region represented by “AP” indicates that the magnetization direction of the storage layer 21 and the magnetization direction of the reference layer 23 are in an antiparallel state in all of the MTJ elements in the memory cell, and the region represented by “P/AP” indicates that in some MTJ elements the magnetization direction of the storage layer 21 and the magnetization direction of the reference layer 23 are in a parallel state and in other MTJ elements the magnetization direction of the storage layer 21 and the magnetization direction of the reference layer 23 are in an antiparallel state in the memory cell.

As can be understood from FIG. 17, the gradient of the voltage relative to the current is greater in the case where the storage layer has a multilayer structure than the case where it has a monolayer structure. This means that the effect of the voltage applied to the MTJ element is greater in the case where the storage layer has a multilayer structure. This increases the crosstalk margin, i.e., the margin for preventing erroneous writing of an MTJ element in the memory cell.

Similar good characteristics may be obtained for the other types of memory cells in which the storage layer has a multilayer structure, like a CoFeB(1.2)/Cu/CoFeB(1.2) structure and a NiFe(1.2)/Ru/NiFe(0.8)/Ta(0.3)/CoFeB(0.8) structure.

In a memory cell including MTJ elements including a storage layer having a multilayer structure, the voltage applied to an MTJ element to switch the magnetization direction of the storage layer has the same absolute value and the opposite polarity to the voltage applied to another MTJ element not to switch the magnetization direction of the storage layer. For example, a negative voltage −V is applied to the reference layer not to switch the magnetization direction of the storage layer of an MTJ element, and a positive voltage +V is applied to the reference layer to switch the magnetization direction of the storage layer of an MTJ element. It is found that this increases the margin further.

An MTJ element having a perpendicular magnetization is formed. A memory cell including an MTJ element 20 with a monolayer storage layer 21 having perpendicular magnetization, and memory cells each including an MTJ element 20 with a multilayer storage layer 21 having perpendicular magnetization are prepared. The monolayer storage layer 21 is formed of CoFeB. Five types of monolayer storage layer 21 having a multilayer structure are formed. For example, a first multilayer structure is Co(Fe)(B)/Pt/Co(Fe)(B), a second multilayer structure is Co(Fe)(B)/Pd/Co(Fe)(B), a third multilayer structure is Co(Fe)(B)/Ni/Co(Fe)(B), a fourth multilayer structure is Co(Fe)(B)/Ni/Co(Fe)(B), and a fifth multilayer structure is CoPt/Ru/CoPt multilayer/(Ta, W, Mo)/CoFeB. The same tendencies as in the case of the memory cells including MTJ elements with in-plane magnetization shown in FIG. 17 are observed for the memory cells including MTJ elements with perpendicular magnetization. Thus, it is found that a storage layer having a multilayer structure is preferable from the viewpoint of an increase in margin.

The first and second embodiments and their specific examples have been described. However, the present invention is not limited to these specific examples. For example, the scope of the present invention includes MTJ elements and SO layers for which those skilled in the art suitably select a specific material, a specific thickness, a specific shape, a specific size, etc. to obtain the same effect as the present invention.

### Third Embodiment

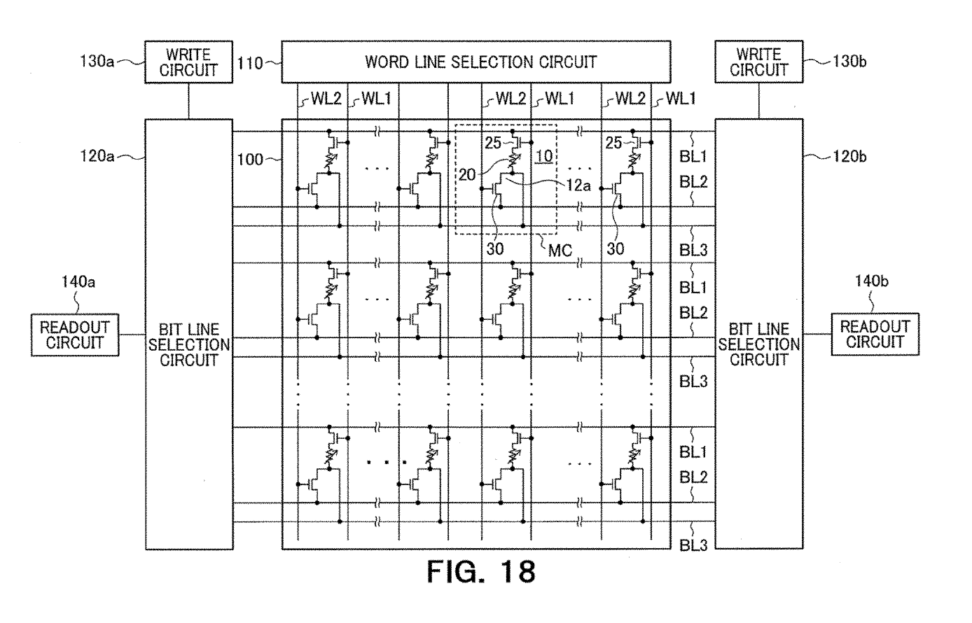

A magnetic memory according to a third embodiment will be described with reference to FIG. 18. FIG. 18 is a circuit diagram of the magnetic memory according to the third embodiment. The magnetic memory according to the third embodiment includes a memory cell array 100 in which memory cells MC are arranged in an array having rows and columns, word lines WL1 and WL2 disposed for the memory cell MCs in the same column, bit lines BL1, BL2, and BL3 disposed for the memory cells MC in the same row, a word line selection circuit 110, bit line selection circuits 120a and 120b, write circuits 130a and 130b, and readout circuits 140a and 140b.

Each memory cell MC corresponds to the memory cell 10 of the magnetic memory according to the first embodiment shown in FIG. 6A, and includes transistors 25 and 30. The memory cell 10 includes a conductive layer 12a and a magnetoresistive element (MTJ element) 20 as shown in FIG. 6A. The memory cell 10 according to the third embodiment does not include the conductive layer 12b shown in FIG. 6A. Therefore, the terminal 13a is connected to the conductive layer 12a.

A first terminal of the magnetoresistive element 20 is connected to the conductive layer 12a via a layer 15, and a second terminal is connected to one of the source and the drain of the transistor 25. The other of the source and the drain of the transistor 25 is connected to the bit line BL1, and the gate is connected to the word line WL1. A first terminal (terminal 13a in FIG. 6A) of the conductive layer 12a is connected to one of the source and the drain of the transistor 30, and a second terminal (terminal 13b in FIG. 6A) is connected to the bit line BL3. The other of the source and the drain of the transistor 30 is connected to the bit line BL2, and the gate is connected to the word line WL2.

### (Write Operation)

A method of writing data to a memory cell will be described below. First, the word line selection circuit 110 applies a high-level potential to the word line WL2 connected to the gate of the transistor 30 of the memory cell MC to which data is to be written, to turn on the transistor 30. At this time, the transistors 30 of other memory cells MC in the same column as the above memory cell MC are also turned on. However, a low-level potential is applied to the word line WL1 connected to the gates of the transistors 30 of the other memory cells MC in the same column as the above memory cell MC and the word lines WL1 and WL2 corresponding to the other columns.

Thereafter, the bit line selection circuits 120a and 120b select the bit lines BL2 and BL3 connected to the memory cell MC to which data is to be written. The write circuits 130a and 130b cause a write current to flow through the selected bit lines BL2 and BL3 from one of the bit line selection circuit 120a and the bit line selection circuit 120b to the other. The write current causes the magnetization direction of the storage layer 21 (FIG. 6A) of the magnetoresistive element 20 to be switched. A write operation is performed in this manner. If the write current is caused to flow in the opposite direction, the magnetization direction of the storage layer 21 (FIG. 6A) of the magnetoresistive element 20 may be switched in a direction opposite to the above case. A write operation may also be performed in this matter.

### (Read Operation)

Next, a method of reading data from a memory cell will be described below. First, a high-level potential is applied to the word line WL1 connected to a memory cell MC from which data is to be read, to turn on the transistor 25 of the memory cell MC. At this time, the transistors 25 of the other memory cells MC in the same column as the memory cell MC from which data is to be read are also turned on. However, a low-level potential is applied to the word line WL2 connected to the gate of the transistor 30 of the memory cell MC from which data is to be read and the word lines WL1 and WL2 corresponding to the other columns.

Thereafter, the bit line selection circuits 120a and 120b select the bit lines BL1 and BL3 connected to the memory cell MC from which data is to be read. The readout circuits 140a and 140b cause a read current to flow through the selected bit lines BL1 and BL3 in a direction from one of the bit line selection circuit 120a and the bit line selection circuit 120b to the other. At this time, whether the magnetization direction of the storage layer 21 (FIG. 6A) and the magnetization direction of the reference layer 23 of the magnetoresistive element 20 is in the parallel state (the same direction) or antiparallel state (in the opposite direction) may be detected by, for example, detecting the voltage between the selected bit lines BL1 and BL3 by means of the readout circuits 140a and 140b. A read operation is performed in this manner.

The word line selection circuit 110, the bit line selection circuits 120a and 120b, the write circuits 130a and 130b, and the readout circuits 140a and 140b are included in the control circuit described in the descriptions of the first and second embodiments.

Like the first embodiment, the current density of the write current flowing through the conductive layer 12a in the third embodiment is improved. As a result, the write efficiency may be improved. Furthermore, the variation in coercive force Hc is reduced. Since the layer 15 acts as an etching stopper of the conductive layer 12a, a magnetic memory with a thin conductive layer may be provided.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A magnetic memory comprising:
a first terminal, a second terminal, and a third terminal;
a first nonmagnetic layer, which is conductive, including a first portion, a second portion, and a third portion, the first portion being disposed between the second portion and the third portion, the second portion being electrically connected to the first terminal, and the third portion being electrically connected to the second terminal;
first magnetoresistive element including a first magnetic layer electrically connected to the third terminal, a second magnetic layer disposed between the first magnetic layer and the first portion, and a second nonmagnetic layer disposed between the first magnetic layer and the second magnetic layer; and
a first layer at least disposed between the first portion and the second magnetic layer, the first layer including at least one of Mg, Al, Si, Hf, or a rare earth element, and the first layer further including at least one of oxygen or nitrogen.

2. The memory according to claim 1, further comprising:
a first circuit configured to apply a voltage to the third terminal and to flow a write current between the first terminal and the second terminal; and
a second circuit configured to flow a react current between the third terminal and the first terminal.

3. The memory according to claim 1, further comprising:
a fourth terminal;
a second magnetoresistive element including a third magnetic layer electrically connected to the fourth terminal, a fourth magnetic layer, and a third nonmagnetic layer disposed between the third magnetic layer and the fourth magnetic layer; and
a second layer including: at least one of Mg, Al, Si, Hf, or a rare earth element; and at least one of oxygen or nitrogen,
the first nonmagnetic layer further including a fourth portion disposed between the first portion and the second portion,
the fourth magnetic layer being disposed between the third nonmagnetic layer and the fourth portion, and
the second layer being disposed between the fourth portion and the fourth magnetic layer.

4. The memory according to claim 3, wherein the first layer and the second layer are connected to each other.

5. The memory according to claim 3, wherein the first layer and the second layer are separated from each other.

6. The memory according to claim 3, further comprising:
a circuit configured to apply a first potential to the third and fourth terminals, to flow a first write current between the first terminal and the second terminal, to apply a second potential to the third or the fourth terminal that is connected to one of the first or the second magnetoresistive element to which data is to be written, and to flow a second write current in a direction opposite to a direction of the first write current between the first terminal and the second terminal.

7. The memory according to claim 3, further comprising:
a circuit configured to apply a first potential to the third terminal and a second potential that is different from the first potential to the fourth terminal and to flow a first write current between the first terminal and the second terminal, and to apply the second potential to the third terminal and the first potential to the fourth terminal and to flow a second write current in a direction opposite to a direction of the first write current between the first terminal and the second terminal.

8. The memory according to claim 1, wherein a thickness of the first layer is 1 nm or less.

9. The memory according to claim 1, wherein the first layer includes at least one of a first material or a second material, the first material includes at least one of magnesium oxide, aluminum nitride, aluminum oxide, silicon nitride, silicon oxide, or hafnium oxide, the second material includes at least one of La, Ce, Pr, Nd, Pm, Sm, Eu, Gd, Tb, Dy, Ho, Er, Tm, or Yb, and the second material further includes at least one of oxygen or nitrogen.

10. The memory according to claim 1, wherein an area of a surface of the first layer facing the first nonmagnetic layer is greater than an area of a surface of the second magnetic layer facing the first layer.

11. The memory according to claim 1, wherein the second magnetic layer includes a fifth magnetic layer, a sixth magnetic layer disposed between the fifth magnetic layer and the first layer, and a fourth nonmagnetic layer disposed between the fifth magnetic layer and the sixth magnetic layer.

12. The memory according to claim 1, wherein the first nonmagnetic layer includes: Cu—Bi or at least one of Ta, W, Re, Os, Ir, Pt, Au, or Ag.

13. The memory according to claim 1, further comprising a first switching element electrically connected to the third terminal, and a second switching element electrically connected to the second terminal.
